(19) United States
(12) Patent Application Publication
(10) Pub. No.: US 2024/0079331 A1
(43) Pub. Date: Mar. 7, 2024

(54) SEMICONDUCTOR DEVICE

(71) Applicant: SAMSUNG ELECTRONICS CO., LTD., SUWON-SI (KR)

(72) Inventors: Azmat RAHEEL, Suwon-si (KR); Jae Hyoung LIM, Suwon-si (KR); Kwan Young CHUN, Suwon-si (KR)

(21) Appl. No.: 18/195,970

(22) Filed: May 11, 2023

(30) Foreign Application Priority Data
Aug. 29, 2022 (KR) 10-2022-0108091

(51) Int. Cl. H01L 23/528; H01L 27/092; H01L 29/06; H01L 29/417; H01L 29/423; H01L 29/775

(52) U.S. Cl. CPC H01L 23/5286; H01L 27/0922; H01L 29/0673; H01L 29/41733; H01L 29/42392; H01L 29/775

(57) ABSTRACT

A semiconductor device includes: first and second active patterns spaced apart from each other in a third direction; a gate electrode covering the first and second active patterns and extending in a second direction; a first source/drain region disposed on opposing sides of the gate electrode and connected to the first active pattern; a second source/drain region disposed on opposing sides of the gate electrode and connected to the second active pattern; a plurality of first upper metal lines extending in a first direction on the second active pattern and spaced apart from each other in the second direction; and a lower metal line extending in the first direction on the first active pattern, wherein the first direction, the second direction and the third direction intersect each other.

### CROSS-REFERENCE TO RELATED APPLICATION

This application claims priority under 35 U.S.C. 119(a) to Korean Patent Application No. 10-2022-0108091 filed on Aug. 29, 2022 in the Korean Intellectual Property Office, the disclosure of which is incorporated by reference herein in its entirety.

### TECHNICAL FIELD

The present inventive concept relates to a semiconductor device.

### DISCUSSION OF THE RELATED ART

Due to the characteristics such as miniaturization, multifunctionality, and/or low manufacturing costs, semiconductor devices have been in relatively high demand in the electronic industry. The semiconductor devices may include semiconductor memory devices that store logical data, semiconductor logic devices that compute logical data, and hybrid semiconductor devices that include memory and logical elements.

With the high-level development of the electronic industry, the demand for the semiconductor devices has been increasing. For instance, the demand for semiconductor devices with high reliability, high speed, and/or reduced manufacturing cost has considerably increased. In order to meet these demanded characteristics, structures in semiconductor devices have been under development.

### SUMMARY

According to an embodiment of the present inventive concept, a semiconductor device includes: first and second active patterns spaced apart from each other in a third direction; a gate electrode covering the first and second active patterns and extending in a second direction; a first source/drain region disposed on opposing sides of the gate electrode and connected to the first active pattern; a second source/drain region disposed on opposing sides of the gate electrode and connected to the second active pattern; a plurality of first upper metal lines extending in a first direction on the second active pattern and spaced apart from each other in the second direction; and a lower metal line extending in the first direction on the first active pattern, wherein the first direction, the second direction and the third direction intersect each other.

According to an embodiment of the present inventive concept, a semiconductor device includes a standard cell region, wherein the standard cell region includes: a first power wiring extending in a first direction and configured to supply a first power voltage to the standard cell region; a second power wiring extending in parallel with the first power wiring and configured to supply a second power voltage different from the first power voltage to the standard cell region; a lower metal line disposed on a same level as the first and second power wirings and disposed between the first and second power wirings, wherein the lower metal line extends in the first direction; a plurality of first upper metal lines extending in the first direction on the lower metal line and spaced apart from each other in a second direction; a plurality of gate electrodes disposed between the lower metal line and the plurality of first upper metal lines, and extending in the second direction, wherein the plurality of gate electrodes are spaced apart from each other in the first direction; a first source/drain region disposed between the plurality of gate electrodes; a second source/drain region disposed between the plurality of gate electrodes and spaced apart from the first source/drain region in a third direction; a first active pattern connected to the first source/drain region and disposed in the gate electrode; and a second active pattern connected to the second source/drain region and disposed in the gate electrode, wherein the second active pattern is spaced apart from the first active pattern in the third direction, wherein the first direction, the second direction and the third direction intersect each other.

According to an embodiment of the present inventive concept, a semiconductor device includes a standard cell region, wherein the standard cell region includes: first and second active patterns spaced apart from each other in a third direction; a plurality of gate electrodes covering the first and second active patterns, and extending in a second direction, wherein the plurality of gate electrodes are spaced apart from each other in a first direction; a first source/drain region disposed between the plurality of gate electrodes and connected to the first active pattern; a second source/drain region disposed between the plurality of gate electrodes and connected to the second active pattern; a plurality of first upper metal lines extending in the first direction on the second active pattern and spaced apart from each other in the second direction; a lower metal line extending in the first direction under the first active pattern; a first power wiring disposed on a same level as the lower metal line, and extending in the first direction, wherein the first power wiring is configured to supply a first power voltage to the first source/drain region; a second power wiring extending in parallel with the first power wiring and configured to supply a second power voltage different from the first power voltage to the second source/drain region; a first gate contact configured to electrically connect some of the plurality of gate electrodes to the lower metal line that is under the plurality of gate electrodes; a plurality of second gate contacts electrically configured to connect the plurality of gate electrodes to the first upper metal line that is disposed on each of the plurality of gate electrodes; a first active contact electrically connected to the first source/drain region that is disposed under the first source/drain region; and a first active via disposed between the lower metal line and the first active contact and configured to electrically connect the lower metal line to the first active contact, wherein when viewed in a plan view, three or four first upper metal lines of the plurality of first upper metal lines are disposed between the first and second power wirings, a width of each of the first and second power wirings in the second direction is greater than a width of the lower metal line in the second direction, and the first direction, the second direction and the third direction intersect each other.

### BRIEF DESCRIPTION OF THE DRAWINGS

The above and features of the present inventive concept will become more apparent by describing in detail exemplary embodiments thereof with reference to the attached drawings, in which:

FIG. 1 is an exemplary layout view describing a semiconductor device according to some embodiments of the present inventive concept;

FIG. 2 is a sectional view taken along line A1-A1′ of FIG. 1;

FIG. 3 is a sectional view taken along line B1-B1′ of FIG. 1:

FIG. 4 is a sectional view taken along line C1-C1′ of FIG. 1;

FIGS. 5 and 6 are views describing the semiconductor device according to some embodiments of the present inventive concept;

FIG. 5 is a sectional view taken along line A1-A1′ of FIG. 1;

FIG. 6 is a sectional view taken along line B1-B1′ of FIG. 1;

FIG. 7 is a sectional view taken along line A1-A1′ of FIG. 1;

FIG. 8 is a sectional view cut taken line B1-B1′ of FIG. 1;

FIG. 9 is a view describing the semiconductor device according to some embodiments of the present inventive concept;

FIG. 10 is a layout view describing the semiconductor device according to some embodiments of the present inventive concept;

FIG. 11 is a sectional view taken along line A2-A2′ of FIG. 10;

FIG. 12 is a sectional view taken along line B2-B2′ of FIG. 10;

FIG. 13 is a sectional view taken along line C2-C2′ of FIG. 10;

FIGS. 14 and 15 are top plan views describing the semiconductor device according to some embodiments of the present inventive concept; and

FIG. 16 is a top plan view describing the semiconductor device according to some embodiments of the present inventive concept.

### DETAILED DESCRIPTION OF THE EMBODIMENT

It is to be understood that the present inventive concept may, however, be embodied in different forms and thus should not be construed as being limited to the embodiments set forth herein.

Although the first, second, etc. are used to describe various elements and/or components, these elements and/or components are not limited by these terms. These terms are only used to distinguish one element or component from another element or component. Therefore, a first element or component may be termed a second element or component without departing from the spirit and scope of the present inventive concept.

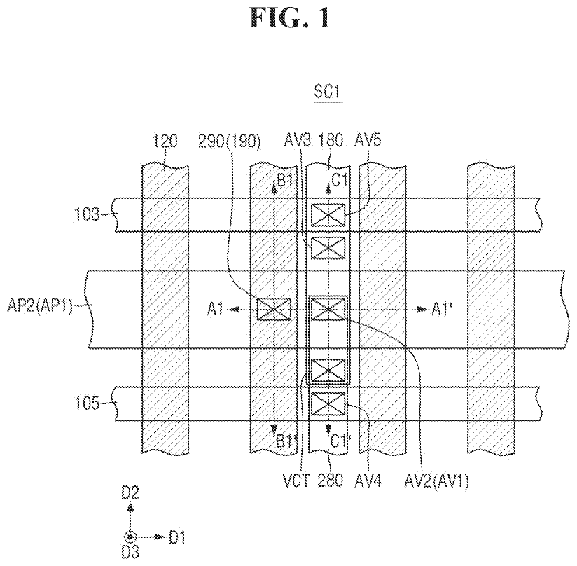

Hereinafter, a semiconductor device according to some embodiments of the present inventive concept will be described with reference to FIGS. 1 to 4.

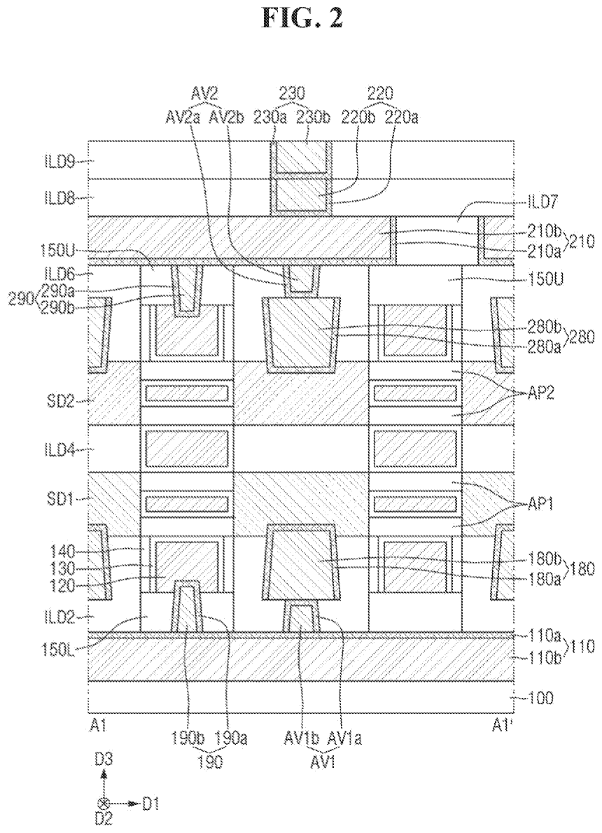

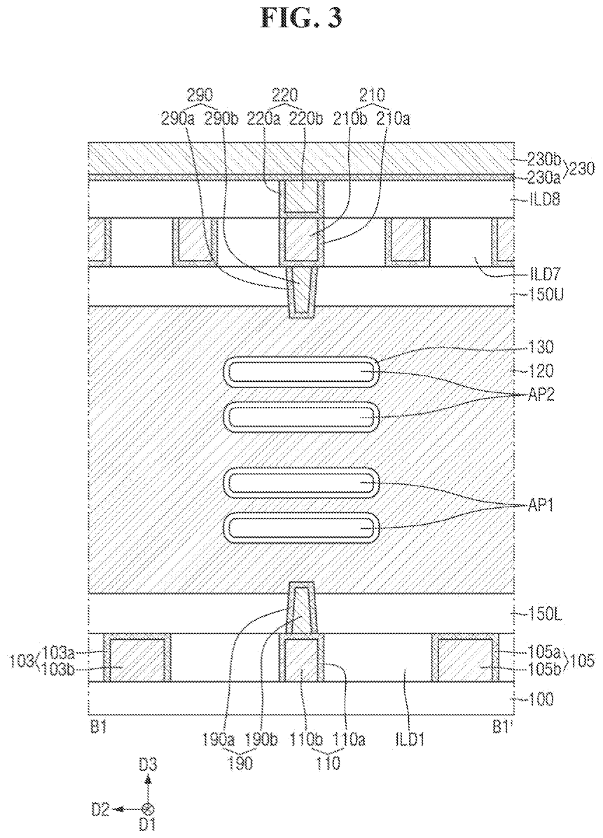

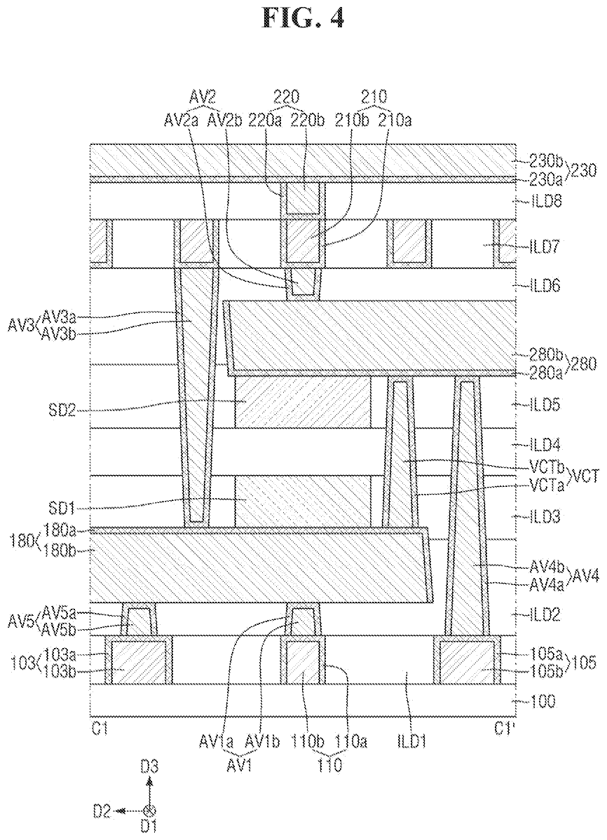

FIG. 1 is a layout view describing a semiconductor device according to some embodiments of the present inventive concept. FIG. 2 is a sectional view taken along line A1-A1′ of FIG. 1. FIG. 3 is a sectional view taken along line B1-B1′ of FIG. 1. FIG. 4 is a sectional view taken along line C1-C1′ of FIG. 1.

Referring to FIGS. 1 to 4, the semiconductor device according to some embodiments of the present inventive concept may include a first standard cell region SC1. FIG. 1 illustrates one first standard cell region SC1; however, this is done for convenience of description, and the present inventive concept is not limited thereto. The semiconductor device according to some embodiments of the present inventive concept may include at least one first standard cell region SC1.

A cell described in this specification may be an expression of various logical elements provided in the steps of: designing the layout of the semiconductor device, manufacturing the semiconductor device, and/or testing the semiconductor device. In other words, the cell may be provided from a cell library of a layout design tool. Alternatively or additionally, the cell may be provided by a producer in the semiconductor manufacturing process.

A standard cell provided in the cell library may be provided in the first standard cell region SC1. The standard cell may refer to one of various cells for implementing a logic circuit. For instance, the standard cell may represent at least one of various logic elements such as an AND gate, a NAND gate, an OR gate, an NOR gate, an XOR gate, and an inverter.

The first standard cell region SC1 may include a substrate 100, a first power wiring 103, a second power wiring 105, a lower metal line 110, a plurality of first upper metal lines 210, an upper metal via 220, a second upper metal line 230, a plurality of gate electrodes 120, first and second active patterns AP1 and AP2, first and second gate contacts 190 and 290, first to fifth active vias AV1, AV1, AV3, AV4 and AV5, and a via contact VCT.

The substrate 100 may be bulk silicon or a silicon-on-insulator (SOI). In addition, the substrate 100 may be a silicon substrate or may include other materials, such as silicon germanium, silicon germanium on insulator (SGOI), indium antimonide, lead tellurium compound, indium arsenide, indium phosphide, gallium arsenide, or gallium antimonide, but the present inventive concept is not limited thereto. In some embodiments of the present inventive concept, the logic circuit of the first standard cell region SC1 may be implemented on the substrate 100.

The first power wiring 103, the second power wiring 105, the lower metal line 110, and a first interlayer insulating film ILD1 may be provided on the substrate 100.

The first power wiring 103 may extend in a first direction D1. The second power wiring 105 may extend in the first direction D1. The second power wiring 105 may extend in parallel with the first power wiring 103. The first power wiring 103 and the second power wiring 105 may be spaced apart from each other in the second direction D2. In this specification, the first direction D1, a second direction D2, and a third direction D3 may intersect each other. For example, the first direction D1, the second direction D2, and the third direction D3 may be substantially perpendicular to each other.

The first power wiring 103 may supply a first power voltage to the first standard cell region SC1. The second power wiring 105 may supply a second power voltage different from the first power voltage to the first standard cell region SC1. For instance, the first power wiring 103 may supply a drain voltage to the first standard cell region SC1, and the second power wiring 105 may supply a source voltage to the first standard cell region SC1. For instance, the first power voltage may be a positive (+) voltage, and the second power voltage may be a ground (GND) voltage or a negative (−) voltage.

The first power wiring 103 may be electrically connected to a first source/drain region SD1 described below. The first power wiring 103 may supply the first power voltage to the first source/drain region SD1. The second power wiring 105 may be electrically connected to a second source/drain region SD2 described below. The second power wiring 105 may supply the second power voltage to the second source/drain region SD2. However, the present inventive concept is not limited thereto.

The lower metal line 110 may be disposed on the same level as the first and second power wirings 103 and 105. The lower metal line 110 may extend in the first direction D1. The lower metal line 110 may extend in parallel with the first and second power wirings 103 and 105. The lower metal line 110 may be spaced apart from the first and second power wirings 103 and 105 in the second direction D2.

The lower metal line 110 may be connected to a gate electrode 120 described below and the first source/drain region SD1. The lower metal line 110 may be disposed under the first active pattern AP1 described below. The lower metal line 110 may be provided between the first active pattern AP1 and the substrate 100. As the lower metal line 110 is disposed under the first active pattern AP1, the arrangement of a first upper metal line 210 described below may be simplified. As the lower metal line 110 is disposed under the first active pattern AP1, the integration of the semiconductor device according to some embodiments of the present inventive concept may be increased.

The first power wiring 103, the second power wiring 105, and the lower metal line 110 may be insulated from each other by the first interlayer insulating film ILD1. The first interlayer insulating film ILD1 may at least partially surround the first power wiring 103, the second power wiring 105, and the lower metal line 110.

The first interlayer insulating film ILD1 may include an insulating material. For instance, the first interlayer insulating film ILD1 may include at least one of silicon oxide, silicon nitride, silicon oxynitride, and/or a low dielectric constant material. The low dielectric constant material may include, for instance, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), Tonen SilaZen (TOSZ), Fluoride Silicate Glass (FSG), polyimide nanofoams such as polypropylene oxide, Carbon Doped silicon Oxide (CDO), Organo Silicate Glass (OSG), SiLK, amorphous Fluorinated Carbon, silica aerogels, silica xerogels, mesoporous silica, or a combination thereof, but the present inventive concept is not limited thereto.

In some embodiments of the present inventive concept, the first power wiring 103, the second power wiring 105, and the lower metal line 110 may have a multi-conductive film structure. For instance, the first power wiring 103 includes a first power wiring barrier film 103a and a first power wiring filling film 103b. The second power wiring 105 includes a second power wiring barrier film 105a and a second power wiring filling film 105b. The lower metal line 110 includes a lower metal line barrier film 110a and a lower metal line filling film 110b.

The first power wiring barrier film 103a, the second power wiring barrier film 105a, and the lower metal line barrier film 110a may each include, for instance, at least one of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and/or a two-dimensional (2D) material.

The first power wiring filling film 103b, the second power wiring filling film 105b, and the lower metal line filling film 110b may each include at least one of aluminum (Al), copper (Cu), tungsten (W), cobalt (Co), ruthenium (Ru), silver (Ag), gold (Au), manganese (Mn), and/or molybdenum (Mo).

A plurality of first upper metal lines 210 may be provided on the lower metal line 110. Each of the plurality of first upper metal lines 210 may extend in the first direction D1. The plurality of first upper metal lines 210 may be spaced apart from each other in the second direction D2. When viewed in a plan view, the plurality of first upper metal lines 210 may be provided between the first and second power wirings 103 and 105. For example, when viewed in a plan view, three or four first upper metal lines 210 may be provided between the first and second power wirings 103 and 105, but the present inventive concept is not limited thereto.

The plurality of first upper metal lines 210 may be connected to the gate electrode 120, the first source/drain region SD1, and the second source/drain region SD2.

The second upper metal line 230 may be disposed on the plurality of first upper metal lines 210. The second upper metal line 230 may intersect the first upper metal lines 210. The second upper metal line 230 may extend in the second direction D2. The first upper metal line 210 and the second upper metal line 230 may be connected to each other. For instance, the first upper metal line 210 and the second upper metal line 230 may be connected to each other using the upper metal via 220 disposed between the first upper metal line 210 and the second upper metal line 230.

Each of the first upper metal line 210, the upper metal via 220 and the second upper metal line 230 may have a multi-conductive film structure. For instance, the first upper metal line 210 includes a first upper metal line barrier film 210a and a first upper metal line filling film 210b. The upper metal via 220 includes an upper metal via barrier film 220a and an upper metal via filling film 220b. The second upper metal line 230 includes a second upper metal line barrier film 230a and a second upper metal line filling film 230b.

The first upper metal line barrier film 210a, the upper metal via barrier film 220a and the second upper metal line barrier film 230a may each include, for instance, tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and/or a two-dimensional (2D) material.

The first upper metal line filling film 210b, the upper metal via filling film 220b, and the second upper metal line filling film 230b may each include at least one of, for example, aluminum (Al), copper (Cu), tungsten (W), cobalt (Co), ruthenium (Ru), silver (Ag), gold (Au), manganese (Mn), and/or molybdenum (Mo).

In some embodiments of the present inventive concept, a seventh interlayer insulating film ILD7 may be disposed between the first upper metal lines 210. The first upper metal lines 210 may be insulated from each other by the seventh interlayer insulating film ILD7. An eighth interlayer insulating film ILD8 may be disposed between the upper metal vias 220. The upper metal vias 220 may be insulated from each other by the eighth interlayer insulating film ILD8. A ninth interlayer insulating film ILD9 may be disposed between the second upper metal lines 230. The second upper metal lines 230 may be insulated from each other by the ninth interlayer insulating film ILD9.

Each of the seventh interlayer insulating film ILD7, the eighth interlayer insulating film ILD8, and the ninth interlayer insulating film ILD9 may include an insulating material. For instance, the seventh interlayer insulating film ILD7, the eighth interlayer insulating film ILD8, and the ninth interlayer insulating film ILD9 may each include the same material as the material included in the first interlayer insulating film ILD1; however, the present inventive concept is not limited thereto.

The first active pattern AP1 and the second active pattern AP2 may be provided between the lower metal line 110 and the first upper metal line 210.

The first active pattern AP1 and the second active pattern AP2 may be spaced apart from each other in the third direction D3. The first active pattern AP1 may be disposed between the lower metal line 110 and the second active pattern AP2. The second active pattern AP2 may be disposed between the first upper metal lines 210 and the first active pattern AP1.

In the semiconductor device according to some embodiments of the present inventive concept, the first active pattern AP1 and the second active pattern AP2, which are used as a channel of the semiconductor device, may be stacked on each other in a vertical direction D3 (e.g., the third direction). Although it is illustrated that the first active pattern AP1 is closer to the substrate 100 than the second active pattern AP2, this is done only for convenience of description; however, the present inventive concept is not limited thereto. In addition, in FIGS. 2 and 3, each of the first active pattern AP1 and the second active pattern AP2 is illustrated to include two nanosheets, but the present inventive concept is not limited thereto.

Each of the first active pattern AP1 and the second active pattern AP2 may include, for example, silicon or germanium that, both of which are semiconductor material. Furthermore, the first active pattern AP1 and the second active pattern AP2 may each include a compound semiconductor, such as a group IV-IV compound semiconductor or a group III-V compound semiconductor.

The group IV-IV compound semiconductor may be, for instance, a binary compound or a ternary compound including at least two of carbon (C), silicon (Si), germanium (Ge) and tin (Sn), or a compound in which these compounds are doped with a group IV element.

The group III-V compound semiconductor may be, for instance, a binary compound, a ternary compound, or a quaternary compound formed by combining at least one of aluminum (Al), gallium (Ga) and indium (In) as a group III element with one of phosphorus (P), arsenic (As) and antimony (Sb) as a group V element.

The plurality of gate electrodes 120 may cover the first and second active patterns AP1 and AP2. The gate electrode 120 may intersect the first and second active patterns AP1 and AP2. The gate electrode 120 may extend long in the second direction D2. In addition, the gate electrode 120 may extend in the third direction D3.

The gate electrode 120 may include, for instance, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC-N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn) and vanadium (V), and a combination thereof.

The gate electrode 120 may include a conductive metal oxide and a conductive metal oxynitride, and have a form where the aforementioned materials are oxidized.

The semiconductor device according to some embodiments of the present inventive concept may further include a gate insulating film 130, a gate spacer 140, and gate capping patterns 150L and 150U. The gate spacer 140 may be disposed on a sidewall of the gate electrode 120.

The gate spacer 140 may extend in the second direction D2. The gate spacer 140 may include, for instance, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC) and a combination thereof.

The gate insulating film 130 may extend along the sidewall and a bottom surface of the gate electrode 120. The gate insulating film 130 may be formed between the gate electrode 120 and the gate spacer 140. The gate insulating film 130 may at least partially surround the circumferences of the first and second active patterns AP1 and AP2.

The gate insulating film 130 may include, for example, silicon oxide, silicon oxynitride, silicon nitride or a high dielectric constant material with a dielectric constant greater than that of silicon oxide. The high dielectric constant material may include, for instance, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The semiconductor device according to some embodiments of the present inventive concept may include a negative capacitance (NC) FET using a negative capacitor. For instance, the gate insulating film 130 may include a ferroelectric material film with ferroelectric properties and a paraelectric material film with paraelectric properties.

The ferroelectric material film may have negative capacitance, and the paraelectric material film may have positive capacitance. For instance, when two or more capacitors are connected in series and the capacitance of each capacitor has a positive value, the total capacitance is less than the capacitance of each individual capacitor. In addition, when at least one of capacitance of two or more capacitors connected in series has a negative value, the total capacitance may have a positive value and simultaneously exceed absolute values of each individual capacitance.

When the ferroelectric material film with negative capacitance and the paraelectric material film with positive capacitance are connected in series, the total capacitance value of the ferroelectric material film and the paraelectric material film connected to each other in series may increase. By using the increase in the total capacitance value, a transistor including the ferroelectric material film may have a subthreshold swing (SS) value of below about 60 mV/decade at room temperature, which is less than or equal to a threshold voltage.

The ferroelectric material film may have the ferroelectric properties. The ferroelectric material film may include, for instance, at least one of hafnium oxide, hafnium zirconium oxide, barium strontium titanium oxide, barium titanium oxide, and/or lead zirconium titanium oxide. Herein, for instance, hafnium zirconium oxide may be a material where hafnium oxide is doped with zirconium (Zr). For another instance, hafnium zirconium oxide may be a compound of hafnium (Hf), zirconium (Zr) and oxygen (O).

The ferroelectric material film may further include a doped dopant. For instance, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr) and/or tin (Sn). The type of dopants included in the ferroelectric material film may vary depending on the ferroelectric material included in the ferroelectric material film.

When the ferroelectric material film includes, for example, hafnium oxide, the dopant included in the ferroelectric material film may include, for instance, at least one of gadolinium (Gd), silicon (Si), zirconium (Zr), aluminum (Al), and/or yttrium (Y).

When the dopant is aluminum (Al), the ferroelectric material film may include aluminum of about 3 to about 8 at % (atomic %). Herein, the ratio of the dopant may be a ratio of aluminum to the sum of hafnium and aluminum.

When the dopant is silicon (Si), the ferroelectric material film may include silicon of about 2 to about 10 at %. When the dopant is yttrium (Y), the ferroelectric material film may include yttrium of about 2 to about 10 at %. When the dopant is gadolinium (Gd), the ferroelectric material film may include gadolinium of about 1 to about 7 at %. When the dopant is zirconium (Zr), the ferroelectric material film may include zirconium of about 50 to about 80 at/o.

The paraelectric material film may have the paraelectric properties. The paraelectric material film may include at least one of, for example, silicon oxide and/or a metal oxide having a high dielectric constant. The metal oxide included in the paraelectric material film may include, for instance, at least one of, for example, hafnium oxide, zirconium oxide, and/or aluminum oxide, but the present inventive concept is not limited thereto.

The ferroelectric material film and the paraelectric material film may include the same material as each other. The ferroelectric material film has the ferroelectric properties, while the paraelectric material film might not have the ferroelectric properties. For instance, when each of the ferroelectric and paraelectric material films include hafnium oxide, the crystal structure of the hafnium oxide included in the ferroelectric material film may differ from that of the hafnium oxide included in the paraelectric material film.

The ferroelectric material film may have a predetermined thickness with ferroelectric properties. The thickness of the ferroelectric material film may be, for instance, about 0.5 to about 10 nm, but the present inventive concept is not limited thereto. As the critical thickness that is indicative of ferroelectric characteristics may vary across different ferroelectric materials, the thickness of the ferroelectric material film may vary depending on the ferroelectric material.

In some embodiments of the present inventive concept, the gate insulating film 130 may include one ferroelectric material film. In an embodiment of the present inventive concept, the gate insulating film 130 may include a plurality of ferroelectric material films spaced apart from each other. The gate insulating film 130 may have a stacked-film structure in which the plurality of ferroelectric material films and the plurality of paraelectric material films are alternately stacked.

The gate capping patterns 150L and 150U may be disposed on an upper surface of the gate electrode 120 and an upper surface of the gate spacer 140. The gate capping patterns 150L and 150U may include the lower gate capping pattern 150L and the upper gate capping pattern 150U.

The lower gate capping pattern 150L may be disposed between the gate electrode 120 and the lower metal line 110. The upper gate capping pattern 150U may be disposed between the gate electrode 120 and the first upper metal line 210.

Each of the lower gate capping pattern 150L and the upper gate capping pattern 150U may include, for instance, at least one of silicon nitride (SiN), silicon oxynitride (SiON), silicon oxide (SiO₂), silicon carbonitride (SiCN) and silicon oxycarbonitride (SiOCN), and a combination thereof.

The semiconductor device according to some embodiments of the present inventive concept may further include a first source/drain region SD1 and a second source/drain region SD2.

The first source/drain region SD1 and the second source/drain region SD2 may be disposed between the plurality of gate electrodes 120. The first source/drain region SD1 and the second source/drain region SD2 may be disposed on both sides of the gate electrode 120.

However, unlike the drawings, according to an embodiment of the present inventive concept, the first source/drain region SD1 and the second source/drain region SD2 may be disposed on one side of the gate electrode 120 and might not be disposed on the other side of the gate electrode 120.

The first source/drain region SD1 and the second source/drain region SD2 may be spaced apart from each other in the third direction D3. For instance, a fourth interlayer insulating film ILD4 may be disposed between the first source/drain region SD1 and the second source/drain region SD2. The fourth interlayer insulating film ILD4 may include an insulating material. For instance, the fourth interlayer insulating film ILD4 may include the same material as the material included in the first interlayer insulating film ILD1.

In some embodiments of the present inventive concept, the first source/drain region SD1 may be connected to the first active pattern AP1. The second source/drain region SD2 may be connected to the second active pattern AP2. Furthermore, the first source/drain region SD1 may be connected to the lower metal line 110. The second source/drain region SD2 may be connected to the first upper metal line 210. The first source/drain region SD1 may be connected to the first power wiring 103. The second source/drain region SD2 may be connected to the second power wiring 105.

The first source/drain region SD1 may include an epitaxial pattern. The first source/drain region SD1 may be a source/drain region of a transistor using the first active pattern AP1 as a channel region. The second source/drain region SD2 may include the epitaxial pattern. The second source/drain region SD2 may be a source/drain region of a transistor using the second active pattern AP2 as a channel region.

The first gate contact 190 may be provided between the gate electrode 120 and the lower metal line 110. The first gate contact 190 may electrically connect the gate electrode 120 to the lower metal line 110. The first gate contact 190 may be connected to the gate electrode 120 by penetrating the lower gate capping pattern 150L. In other words, one side of the first gate contact 190 may be connected to the gate electrode 120, and the other side of the first gate contact 190 may be connected to the lower metal line 110.

The second gate contact 290 may be provided between the gate electrode 120 and the first upper metal line 210. The second gate contact 290 may electrically connect the gate electrode 120 to the first upper metal line 210. The second gate contact 290 may be connected to the gate electrode 120 by penetrating the upper gate capping pattern 150U. In other words, one side of the second gate contact 290 may be connected to the gate electrode 120, and the other side of the second gate contact 290 may be connected to the first upper metal line 210.

In some embodiments of the present inventive concept, the first and second gate contacts 190 and 290 may overlap each other in the third direction D3. For example, the first and second gate contacts 190 and 290 may be aligned with each other in the third direction D3. However, the present inventive concept is not limited thereto.

In some embodiments of the present inventive concept, the gate electrode 120 and the lower metal line 110 may be electrically connected to each other via the first gate contact 190. Furthermore, the gate electrode 120 and the first upper metal line 210 may be electrically connected to each other via the second gate contact 290. The lower metal line 110 and the first upper metal line 210 may be connected to each other via the gate electrode 120. Accordingly, a signal provided to the lower metal line 110 may be transmitted to the first upper metal line 210. In addition, a signal provided to the first upper metal line 210 may be transmitted to the lower metal line 110.

The semiconductor device according to some embodiments of the present inventive concept may further include first and second active contacts 180 and 280.

The first active contact 180 may be provided between the first source/drain region SD1 and the lower metal line 110. For example, a portion of the first active contact 180 may penetrate the first source/drain region SD1. The first active contact 180 may electrically connect the first source/drain region SD1 to the lower metal line 110. The first active contact 180 and the lower metal line 110 may be electrically connected to each other using a first active via AV1 described below. The first active contact 180 may extend in the second direction D2, but the present inventive concept is not limited thereto. A part of the sidewall of the first active contact 180 may be covered by a second interlayer insulating film ILD2. The second interlayer insulating film ILD2 may electrically separate the first active contact 180 from other components.

The second active contact 280 may be provided between the second source/drain region SD2 and the first upper metal line 210. The second active contact 280 may electrically connect the second source/drain region SD2 to the first upper metal line 210. The second active contact 280 and the first upper metal line 210 may be electrically connected to each other using a second active via AV2 described below. The second active contact 280 may extend in the second direction D2, but the present inventive concept is not limited thereto. The second active contact 280 may extend in a direction opposite to the first active contact 180. A part of the sidewall of the second active contact 280 may be covered by a sixth interlayer insulating film ILD6. The sixth interlayer insulating film ILD6 may electrically separate the second active contact 280 from other components.

Each of the second interlayer insulating film ILD2 and the sixth interlayer insulating film ILD6 may include an insulating material. For instance, each of the second interlayer insulating film ILD2 and the sixth interlayer insulating film ILD6 may include the same material as the material included in the first interlayer insulating film ILD1.

In some embodiments of the present inventive concept, the first gate contact 190, the second gate contact 290, the first active contact 180 and the second active contact 280 may each have a multi-conductive film structure. For instance, the first gate contact 190 includes a first gate contact barrier film 190a and a first gate contact filling film 190b. The second gate contact 290 includes a second gate contact barrier film 290a and a second gate contact filling film 290b. The first active contact 180 includes a first active contact barrier film 180a and a first active contact filling film 180b. The second active contact 280 includes a second active contact barrier film 280a and a second active contact filling film 280b.

The first gate contact barrier film 190a, the second gate contact barrier film 290a, the first active contact barrier film 180a, and the second active contact barrier film 280a may each include, for example, at least one of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and/or a two-dimensional (2D) material.

The first gate contact filling film 190b, the second gate contact filling film 290b, the first active contact filling film 180b, and the second active contact filling film 280b may each include at least one of, for example, aluminum (Al), copper (Cu), tungsten (W), cobalt (Co), ruthenium (Ru), silver (Ag), gold (Au), manganese (Mn) and/or molybdenum (Mo).

The first active via AV1 may be provided between the lower metal line 110 and the first active contact 180. The first active via AV1 may electrically connect the lower metal line 110 to the first active contact 180. The width of the first active via AV1 may gradually increase as the first active via AV1 approaches the lower metal line 110 from the first active contact 180, but the present inventive concept is not limited thereto. The first active via AV1 may be at least partially surrounded by the second interlayer insulating film ILD2.

The second active via AV2 may be provided between the first upper metal line 210 and the second active contact 280. The second active via AV2 may electrically connect the first upper metal line 210 to the second active contact 280. The width of the second active via AV2 may gradually increase as the second active via AV2 approaches the first upper metal line 210 from the second active contact 280, but the present inventive concept is not limited thereto. The second active via AV2 may be at least partially surrounded by the sixth interlayer insulating film ILD6.

The third active via AV3 may be provided between the first active contact 180 and the first upper metal line 210. The third active via AV3 may electrically connect the first upper metal line 210 to the first active contact 180. The width of the third active via AV3 may gradually increase as the third active via AV3 approaches the first upper metal line 210 from the first active contact 180, but the present inventive concept is not limited thereto. The third active via AV3 may be at least partially surrounded by a third interlayer insulating film ILD3, the fourth interlayer insulating film ILD4, a fifth interlayer insulating film ILD5, and the sixth interlayer insulating film ILD6. The third active via AV3 may penetrate the third interlayer insulating film ILD3, the fourth interlayer insulating film ILD4, the fifth interlayer insulating film ILD5, and the sixth interlayer insulating film ILD6.

Each of the third interlayer insulating film ILD3 and the fifth interlayer insulating film ILD5 may include an insulating material. For example, each of the third interlayer insulating film ILD3 and the fifth interlayer insulating film ILD5 may include the same material as the material included in the first interlayer insulating film ILD1.

In some embodiments of the present inventive concept, a part of the third active via AV3 may overlap the second active via AV2, the second active contact 280, the second source/drain region SD2, the first source/drain region SD1 and the via contact VCT in the second direction D2. Furthermore, a part of the third active via AV3 may overlap a part of the fourth active via AV4 in the second direction D2.

The fourth active via AV4 may be provided between the second active contact 280 and the second power wiring 105. The fourth active via AV4 may electrically connect the second power wiring 105 to the second active contact 280. The width of the fourth active via AV4 may gradually increase as the fourth active via AV4 approaches the second power wiring 105 from the second active contact 280, but the present inventive concept is not limited thereto. The fourth active via AV4 may be at least partially surrounded by the fifth interlayer insulating film ILD5, the fourth interlayer insulating film ILD4, the third interlayer insulating film ILD3, and the second interlayer insulating film ILD2. The fourth active via AV4 may penetrate the fifth interlayer insulating film ILD5, the fourth interlayer insulating film ILD4, the third interlayer insulating film ILD3, and the second interlayer insulating film ILD2.

In some embodiments of the present inventive concept, a part of the fourth active via AV4 may overlap the first active via AV1, the fifth active via AV5, the first active contact 180, the first source/drain region SD1, the second source/drain region SD2, and the via contact VCT in the second direction D2. In addition, a part of the fourth active via AV4 may overlap a part of the third active via AV3 in the second direction D2.

The fifth active via AV5 may be provided between the first active contact 180 and the first power wiring 103. The fifth active via AV5 may electrically connect the first active contact 180 to the first power wiring 103. The fifth active via AV5 may be at least partially surrounded by the second interlayer insulating film ILD2.

In some embodiments of the present inventive concept, each of the first to fifth active vias AV1, AV2, AV3, AV4 and AV5 may have a multi-conductive film structure. For example, the first active via AV1 includes a first active via barrier film AV1a and a first active via filling film AV1b. The second active via AV2 includes a second active via barrier film AV2a and a second active via filling film AV2b. The third active via AV3 includes a third active via barrier film AV3a and a third active via filling film AV3b. The fourth active via AV4 includes a fourth active via barrier film AV4a and a fourth active via filling film AV4b. The fifth active via AV5 includes a fifth active via barrier film AV5a and a fifth active via filling film AV5b.

The first active via barrier film AV1a, the second active via barrier film AV2a, the third active via barrier film AV3a, the fourth active via barrier film AV4a and the fifth active via barrier film AV5a may each include, for instance, at least one of tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and/or a two-dimensional (2D) material.

The first active via filling film AV1b, the second active via filling film AV2b, the third active via filling film AV3b, the fourth active via filling film AV4b and the fifth active via filling film AV5b may each include at least one of, for example, aluminum (Al), copper (Cu), tungsten (W), cobalt (Co), ruthenium (Ru), silver (Ag), gold (Au), manganese (Mn) and/or molybdenum (Mo).

The via contact VCT may be disposed between the first active contact 180 and the second active contact 280. The via contact VCT may electrically connect the first active contact 180 to the second active contact 280. The via contact VCT may be at least partially surrounded by the third interlayer insulating film ILD3, the fourth interlayer insulating film ILD4, and the fifth interlayer insulating film ILD5. The via contact VCT may penetrate the third interlayer insulating film ILD3, the fourth interlayer insulating film ILD4, and the fifth interlayer insulating film ILD5.

In some embodiments of the present inventive concept, the via contact VCT may have a multi-conductive film structure. For instance, the via contact VCT includes a via contact barrier film VCTa and a via contact filling film VCTb.

The via contact barrier film VCTa may include, for instance, at least one of, for example, tantalum (Ta), tantalum nitride (TaN), titanium (Ti), titanium nitride (TiN), titanium silicon nitride (TiSiN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and/or a two-dimensional (2D) material.

The via contact filling film VCTb may include, for example, at least one of aluminum (Al), copper (Cu), tungsten (W), cobalt (Co), ruthenium (Ru), silver (Ag), gold (Au), manganese (Mn), and/or molybdenum (Mo).

Although FIGS. 1 to 4 illustrate a complementary FET (CFET) including a nanosheet as a semiconductor device provided in the first standard cell region SC1, this is merely an example. As another example, the semiconductor device provided in the first standard cell region SC1 may include a fin-type transistor (FinFET), a tunneling transistor (tunneling FET), a transistor including a nanowire, a transistor including a nanosheet, a vertical FET (VFET), or a three-dimensional (3D) transistor. In addition, the semiconductor device provided in the first standard cell region SC1 may include a bipolar junction transistor and a transverse double diffusion transistor (LDMOS).

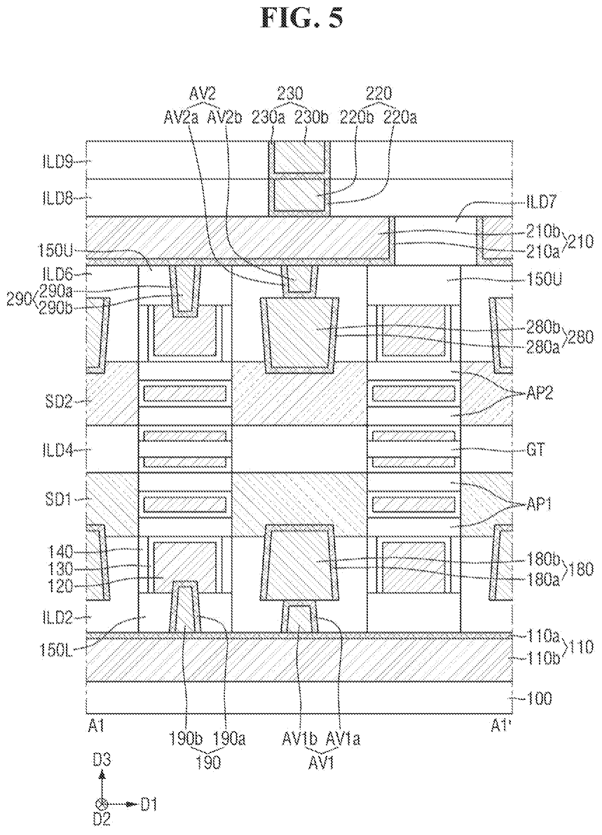

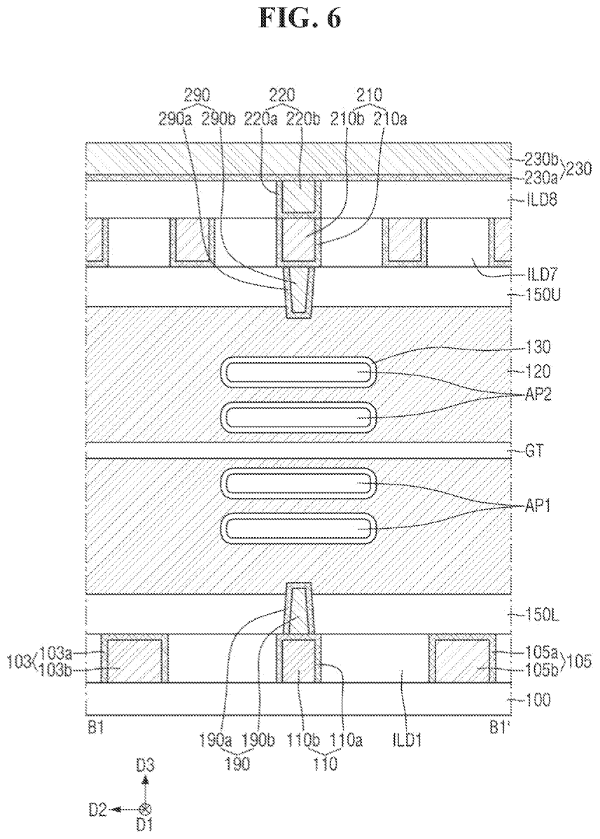

Hereinafter, the semiconductor device according to some embodiments of the present inventive concept will be described with reference to FIGS. 5 to 16.

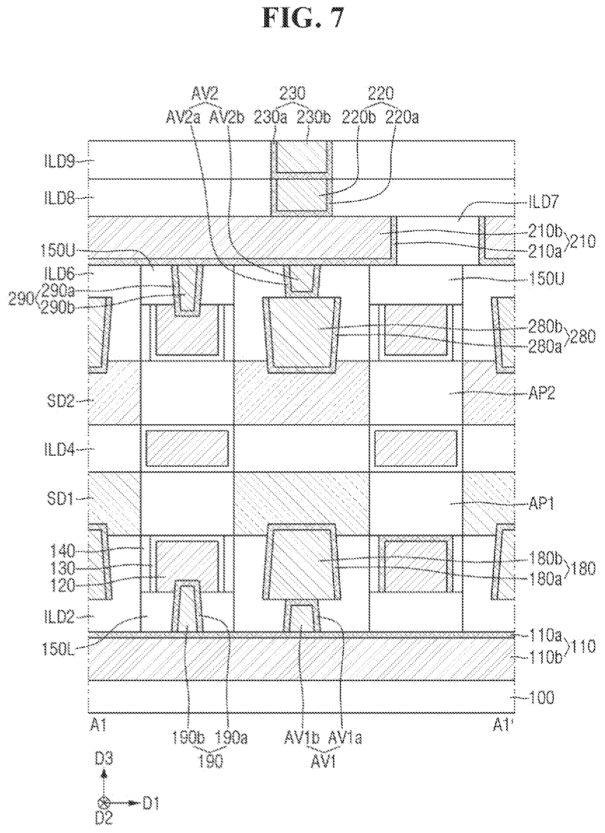

FIGS. 5 and 6 are views describing the semiconductor device according to some embodiments of the present inventive concept. For convenience of description, the differences from the content described with reference to FIGS. 1 to 4 will be mainly described. For reference, FIG. 5 may be a sectional view taken along line A1-A1′ of FIG. 1, and FIG. 6 may be a sectional view taken along line B1-B1′ of FIG. 1.

Referring to FIGS. 5 and 6, the semiconductor device according to some embodiments of the present inventive concept may further include a gate separation structure GT.

The gate separation structure GT may separate the gate electrode 120. The gate separation structure GT may be provided between the first active pattern AP1 and the second active pattern AP2. The gate separation structure GT may overlap the fourth interlayer insulating film ILD4 in the first direction D1. The gate separation structure GT may extend in the second direction D2. The gate separation structure GT may penetrate the gate insulating film 130.

The gate separation structure GT may include, for example, silicon nitride (SiN), silicon oxide (SiO₂), and a combination film thereof. Although the gate separation structure GT is illustrated to be a single film, this is done for convenience of description and the present inventive concept is not limited thereto. The gate separation structure GT may be a multi-film.

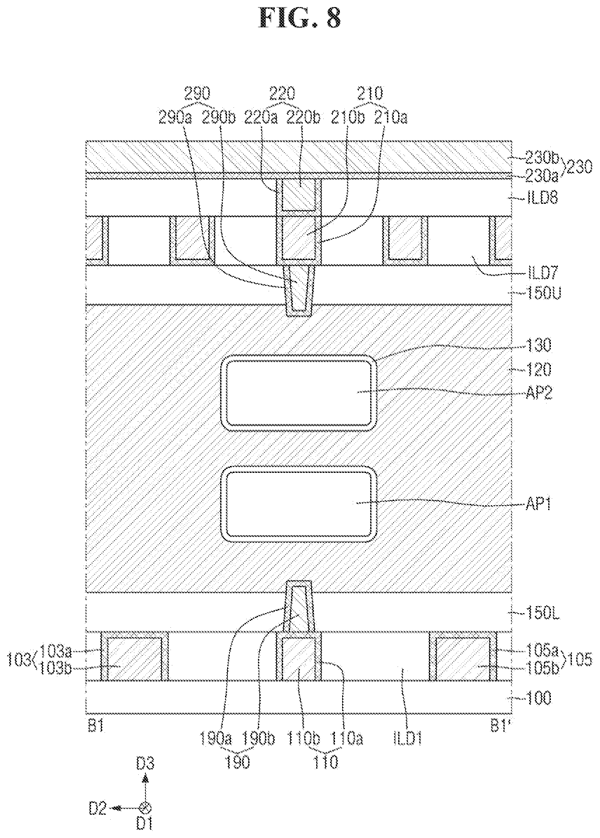

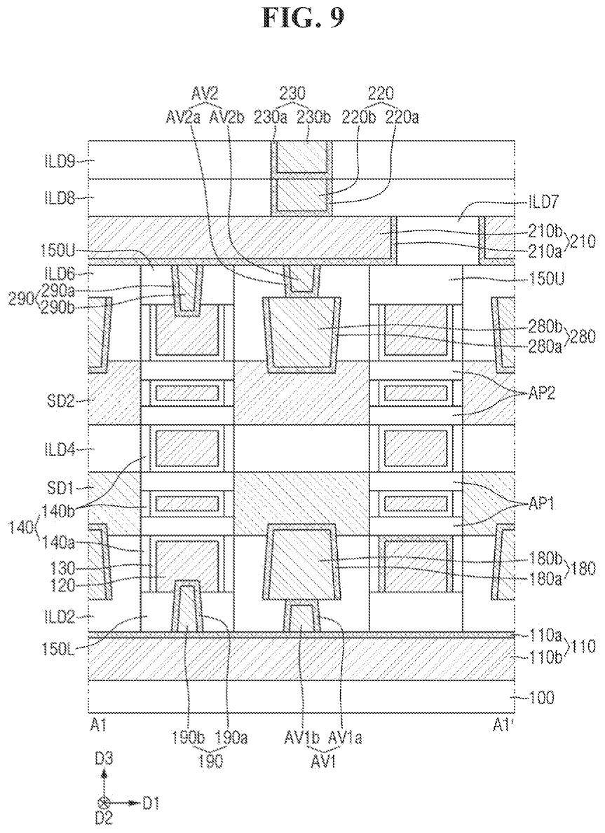

FIGS. 7 and 8 are views describing the semiconductor device according to some embodiments of the present inventive concept. For convenience of description, the differences from the content described with reference to FIGS. 1 to 4 will be mainly described. For reference, FIG. 7 may be a sectional view taken along line A1-A1′ of FIG. 1, and FIG. 8 may be a sectional view taken along line B1-B1′ of FIG. 1.

Referring to FIGS. 7 and 8, one first active pattern AP1 and one second active pattern AP2 may be provided.

The first active pattern AP1 may be disposed between the first source/drain regions SD1. The first active pattern AP1 may overlap the first source/drain region SD1 in the first direction D1. For example, the first active pattern AP1 may completely overlap the first source/drain region SD1 in the first direction D1. The second active pattern AP2 may be disposed between the second source/drain regions SD2. The second active pattern AP2 may overlap the second source/drain region SD2 in the first direction D1. For example, the second active pattern AP2 may completely overlap the second source/drain region SD2 in the first direction D1.

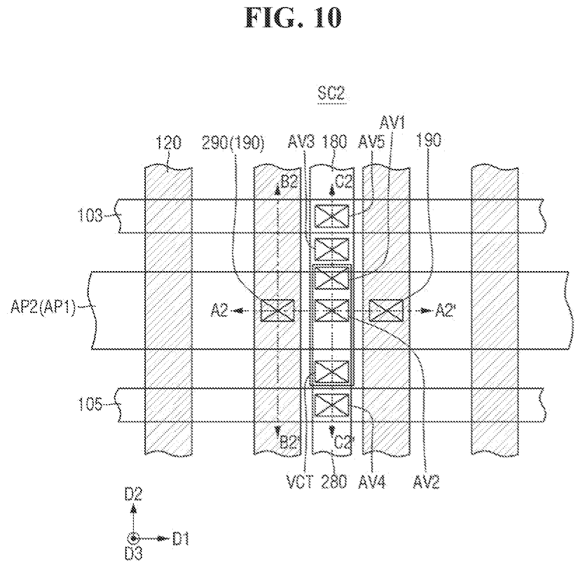

FIG. 9 is a view describing the semiconductor device according to some embodiments of the present inventive concept. For convenience of description, the differences from the content described with reference to FIGS. 1 to 4 will be mainly described. For reference, FIG. 9 may be a sectional view taken along line A1-A1′ of FIG. 1.

Referring to FIG. 9, the gate spacer 140 may include an outer spacer 140a and an inner spacer 140b.

The inner spacer 140b may be disposed between the first active patterns AP1, between the second active patterns AP2, or between the first active pattern AP1 and the second active pattern AP2. The inner spacer 140b may be disposed between the first source/drain region SD1 and the gate insulating film 130, between the second source/drain region SD2 and the gate insulating film 130, or between the fourth interlayer insulating film ILD4 and the gate insulating film 130.

The outer spacer 140a may be disposed between the first active pattern AP1 and the lower gate capping pattern 150L. In addition, the outer spacer 140a may be disposed between the second active pattern AP2 and the upper gate capping pattern 150U.

The outer spacer 140a and the inner spacer 140b may each include at least one of, for example, silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbide (SiOC), and a combination thereof.

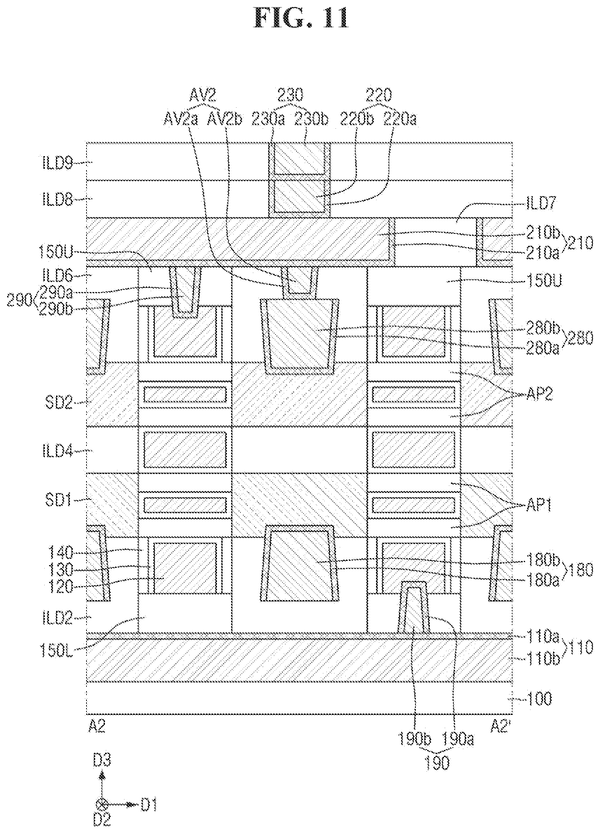

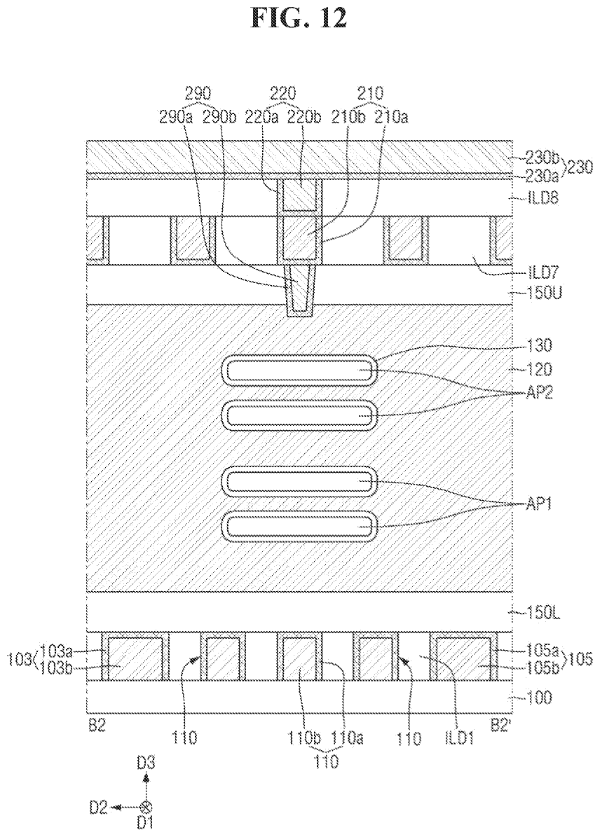

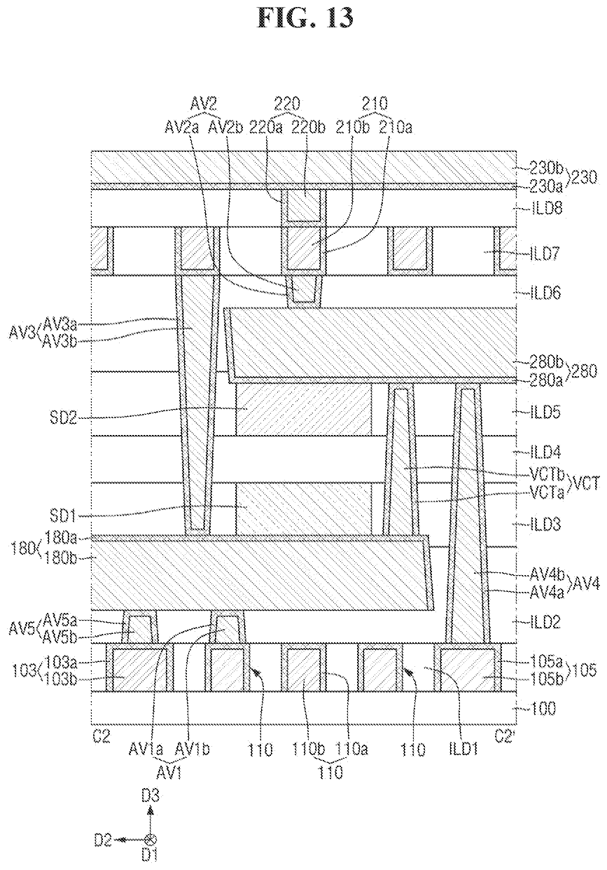

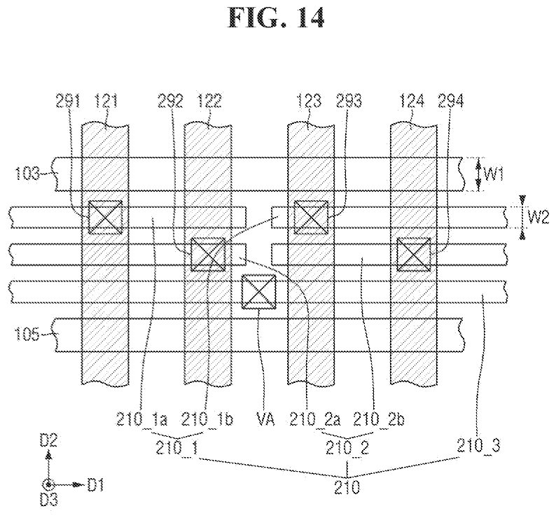

FIG. 10 is a layout view describing the semiconductor device according to some embodiments of the present inventive concept. FIG. 11 is a sectional view taken along line A2-A2′ of FIG. 10. FIG. 12 is a sectional view taken along line B2-B2′ of FIG. 10. FIG. 13 is a sectional view taken along line C2-C2′ of FIG. 10. For convenience of description, the differences from the content described with reference to FIGS. 1 to 4 will be mainly described.

Referring to FIGS. 10 to 13, the semiconductor device according to some embodiments of the present inventive concept may include a second standard cell region SC2. Although FIG. 10 illustrates one second standard cell region SC2, this is done for convenience of description and the present inventive concept is not limited thereto. The semiconductor device according to some embodiments of the present inventive concept may include at least one second standard cell region SC2.

In the second standard cell region SC2, the first gate contact 190 and the second gate contact 290 do not overlap each other in the third direction D3.

For instance, the gate electrode 120 may include a first gate electrode and a second gate electrode spaced apart from each other in the first direction D1. When the first gate contact 190 is connected to the first gate electrode, the second gate contact 290 may be connected to the first gate electrode and the second gate electrode spaced apart from the first gate electrode in the first direction D1.

In that case, when viewed in a plan view, a third gate contact may be disposed on the first gate electrode in a position spaced apart from the first gate contact 190 in the second direction D2. The third gate contact may be provided between the first upper metal line 210 and the first gate electrode. The third gate contact may electrically connect the first upper metal line 210 to the first gate electrode. The lower metal line 110 and the first upper metal line 210 may be electrically connected to each other using the third gate contact and the first gate contact 190.

In addition, when viewed in a plan view, a fourth gate contact may be disposed on the second gate electrode in a position spaced apart from the second gate contact 290 in the second direction D2. The fourth gate contact may be provided between the lower metal line 110 and the second gate electrode. The fourth gate contact may electrically connect the lower metal line 110 to the second gate electrode. The lower metal line 110 and the first upper metal line 210 may be electrically connected to each other using the fourth gate contact and the second gate contact 290.

In some embodiments of the present inventive concept, at least one lower metal line 110 may be provided. For instance, three lower metal lines 110 may be provided. Each of the lower metal lines 110 may extend in the first direction D1. The lower metal lines 110 may be spaced apart from each other in the second direction D2.

In some embodiments of the present inventive concept, the first active via AV1 and the second active via AV2 do not overlap each other in the third direction D3. For instance, the lower metal line 110 may include a first lower metal line and a second lower metal line spaced apart from each other in the second direction D2. The first active via AV1 may be disposed between the first active contact 180 and the first lower metal line of the lower metal lines 110. The first active via AV1 may electrically connect the first active contact 180 to the first lower metal line of the lower metal lines 110. The second active via AV2 may be disposed between the second active contact 280 and the first upper metal line 210. In that case, the first upper metal line 210 and the first lower metal line of the lower metal lines 110, which is connected to the first active via AV1, do not overlap each other in the third direction D3. However, the present inventive concept is not limited thereto.

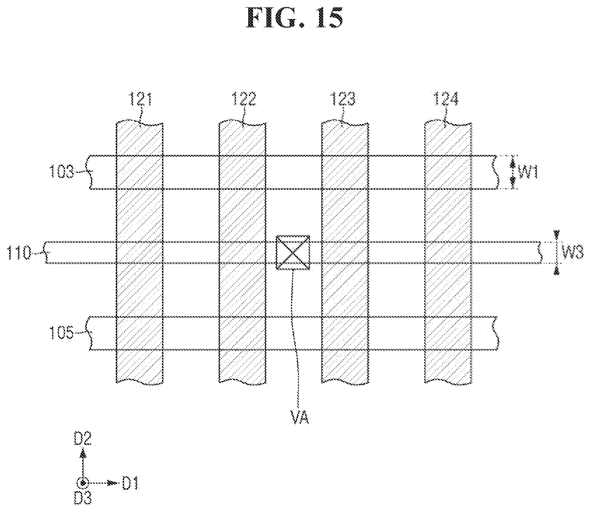

FIGS. 14 and 15 are top plan views describing the semiconductor device according to some embodiments of the present inventive concept. For reference, FIG. 14 is a top plan view of a semiconductor device according to some embodiments of the present inventive concept, as seen from above, and FIG. 14 may be a top plan view of a semiconductor device according to some embodiments of the present inventive concept, as seen from below.

First, referring to FIG. 14, when viewed in a plan view, the semiconductor device according to some embodiments of the present inventive concept may include the first power wiring 103, the second power wiring 105, the first upper metal line 210, first to fourth gate electrodes 121, 122, 123 and 124, first to fourth sub-gate contacts 291, 292, 293 and 294, and a via VA.

The first power wiring 103 and the second power wiring 105 may extend in the first direction D1 and be spaced apart from each other in the second direction D2. The first to fourth gate electrodes 121, 122, 123 and 124 may extend in the second direction D2 and be spaced apart from each other in the first direction D1.

In some embodiments of the present inventive concept, when viewed in a plan view, three upper metal lines 210 may be disposed between the first power line 103 and the second power line 105. For instance, the first upper metal line 210 may include a first sub-line 210_1, a second sub-line 210_2, and a third sub-line 210_3. The first sub-line 210_1, the second sub-line 210_2, and the third sub-line 2103 may be spaced apart from each other in the second direction D2. Among the first sub-line 210_1, the second sub-line 210_2, and the third sub-line 210_3, the first sub-line 210_1 may be closest to the first power wiring 103. Among the first sub-line 210_1, the second sub-line 210_2, and the third sub-line 210_3, the third sub-line 2103 may be closest to the second power wiring 105. The second sub-line 210_2 may be provided between the first sub-line 210_1 and the third sub-line 210_3.

In some embodiments of the present inventive concept, the first sub-line 210_1 includes a first portion 210_1a and a second portion 210_1b spaced apart from each other. The first portion 210_1a of the first sub-line 210_1 may be connected to the first gate electrode 121. For instance, the first portion 210_1a of the first sub-line 210_1 may be connected to the first gate electrode 121 through the first sub-gate contact 291. The second portion 210_1b of the first sub-line 210_1 may be connected to the third gate electrode 123. For instance, the second portion 210_1b of the first sub-line 2101 may be connected to the third gate electrode 123 through the third sub-gate contact 293.

The second sub-line 210_2 includes a first portion 210_2a and a second portion 210_2b spaced apart from each other in the first direction D1. The first portion 210_2a of the second sub-line 210_2 may be connected to the second gate electrode 122. For instance, the first portion 210_2a of the second sub-line 210_2 may be connected to the second gate electrode 122 through the second sub-gate contact 292. The second portion 210_2b of the second sub-line 210_2 may be connected to the fourth gate electrode 124. For instance, the second portion 210_2b of the second sub-line 210_2 may be connected to the fourth gate electrode 124 through the fourth sub-gate contact 294.

The third sub-line 210_3 may extend in the first direction D1. The third sub-line 210_3 may be connected to the via VA. The via VA may be the first to third active vias or the via contact described with reference to FIGS. 1 to 4, but the present inventive concept is not limited thereto.

In some embodiments of the present inventive concept, a width W1 of the first power line 103 in the second direction D2 exceeds a width W2 of the first upper metal line 210 in the second direction D2. Likewise, the width of the second power wiring 105 in the second direction D2 exceeds a width W2 of the first upper metal line 210 in the second direction D2. For example, the width W1 of the first power wiring 103 may be the same as or different from the width of the second power wiring 105. However, the present inventive concept is not limited thereto.

Referring to FIG. 15, the semiconductor device according to some embodiments of the present inventive concept includes the lower metal line 110 extending in the first direction D1 between the first power wiring 103 and the second power wiring 105. The lower metal line 110 may extend long in the first direction D1. The via VA may be connected to the lower metal line 110. The via VA may be the first to third active vias or the via contact described with reference to FIGS. 1 to 4, but the present inventive concept is not limited thereto.

In some embodiments of the present inventive concept, the width W1 of the first power wiring 103 in the second direction D2 exceeds a width W3 of the lower metal line 110 in the second direction D2. Likewise, the width of the second power wiring 105 in the second direction D2 exceeds the width W3 of the lower metal line 110 in the second direction D2. However, the present inventive concept is not limited thereto.

The semiconductor device according to some embodiments of the present inventive concept includes the lower metal line 110 and the first upper metal line 210. The lower metal line 110 is disposed in a lower part of the semiconductor device, and the first upper metal line 210 is disposed in an upper part of the semiconductor device. Inclusion of the lower metal line 110 may reduce the number of first upper metal lines 210 disposed in the upper part of the semiconductor device. Accordingly, the semiconductor device with increased integration may be produced.

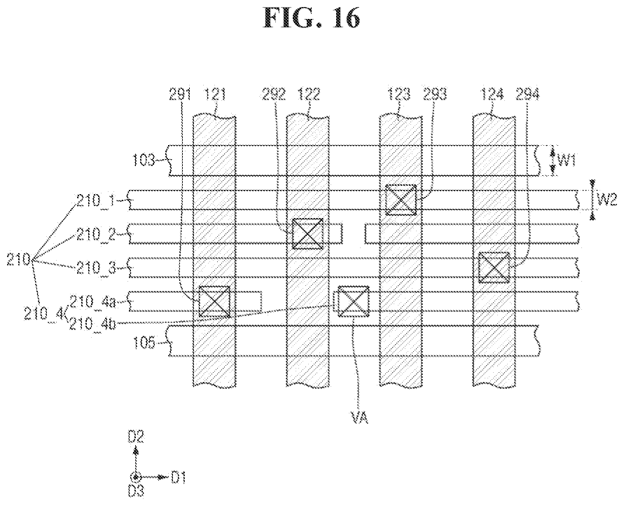

FIG. 16 is a top plan view describing the semiconductor device according to some embodiments of the present inventive concept. For convenience of description, the differences from the content described with reference to FIGS. 14 to 15 will be mainly described.

Referring to FIG. 16, when viewed in a plan view, four first upper metal lines 210 may be disposed between the first power wiring 103 and the second power wiring 105. For instance, the first upper metal line 210 may include the first sub-line 210_1, the second sub-line 210_2, the third sub-line 210_3, and a fourth sub-line 210_4.

The first sub-line 210_1, the second sub-line 210_2 and the third sub-line 210_3 may extend long in the first direction D1. However, the fourth sub-line 210_4 includes a first portion 210_4a and a second portion 210_4b spaced apart from each other in the first direction D1. The first sub-line 210_1 is connected to the third gate electrode 123 through the third sub-gate contact 293. The second sub-line 210_2 is connected to the second gate electrode 122 through the second sub-gate contact 292. The third sub-line 210_3 is connected to the fourth gate electrode 124 through the fourth sub-gate contact 294. The first portion 210_4a of the fourth sub-line 210_4 is connected to the first gate electrode 121 through the first sub-gate contact 291. The via VA may be connected to the second portion 210_4b of the fourth sub-line 210_4.

The semiconductor device according to some embodiments of the present inventive concept includes the lower metal line 110 and a first upper metal line 210. The lower metal line 110 is disposed in the lower part of the semiconductor device, and the first upper metal line 210 is disposed in the upper part of the semiconductor device. As the lower metal line 110 is disposed in the lower part of the semiconductor device, the arrangement of the first upper metal line 210 disposed in the upper part of the semiconductor device may be simplified. Furthermore, a region where the upper metal via 220 of FIG. 2, which is connected to the first upper metal line 210, is formed may be more easily secured. Accordingly, the semiconductor device with increased reliability may be produced.

While the present inventive concept has been described with reference to exemplary embodiments thereof, it will be understood by those of ordinary skill in the art that various changes in form and details may be made thereto without departing from the spirit and scope of the present inventive concept.

What is claimed is:

1. A semiconductor device, comprising:
first and second active patterns spaced apart from each other in a third direction;
a gate electrode covering the first and second active patterns and extending in a second direction;
a first source/drain region disposed on opposing sides of the gate electrode and connected to the first active pattern;
a second source/drain region disposed on opposing sides of the gate electrode and connected to the second active pattern;
a plurality of first upper metal lines extending in a first direction on the second active pattern and spaced apart from each other in the second direction; and
a lower metal line extending in the first direction on the first active pattern,
wherein the first direction, the second direction and the third direction intersect each other.

2. The semiconductor device of claim 1, further comprising:
a first active contact electrically connected to the first source/drain region and disposed between the lower metal line and the first source/drain region.

3. The semiconductor device of claim 2, further comprising:
a first active via disposed between the first active contact and the lower metal line and configured to electrically connect the first active contact to the lower metal line.

4. The semiconductor device of claim 2, further comprising a second active via disposed between the first active contact and the first upper metal line and configured to electrically connect the first active contact to the first upper metal line.

5. The semiconductor device of claim 2, further comprising:
a second active contact electrically connected to the second source/drain region and disposed between the first upper metal line and the second source/drain region.

6. The semiconductor device of claim 5, further comprising:
a via contact disposed between the first active contact and the second active contact and configured to electrically connect the first active contact to the second active contact.

7. The semiconductor device of claim 1, further comprising:
first and second power wirings disposed on a same level as the lower metal line, and extending in the first direction, wherein the first and second power wirings are spaced part from each other in the second direction,
wherein a width of each of the first and second power wirings in the second direction is greater than a width of the lower metal line in the second direction.

8. The semiconductor device of claim 1, further comprising:
a second upper metal line extending in the second direction on the first upper metal line and connected to the first upper metal line.

9. The semiconductor device of claim 1, further comprising:
a gate contact configured to electrically connect the gate electrode to the lower metal line and disposed between the gate electrode and the lower metal line.

10. A semiconductor device comprising a standard cell region, wherein the standard cell region comprises:
a first power wiring extending in a first direction and configured to supply a first power voltage to the standard cell region;
a second power wiring extending in parallel with the first power wiring and configured to supply a second power voltage different from the first power voltage to the standard cell region;
a lower metal line disposed on a same level as the first and second power wirings and disposed between the first and second power wirings, wherein the lower metal line extends in the first direction;
a plurality of first upper metal lines extending in the first direction on the lower metal line and spaced apart from each other in a second direction;
a plurality of gate electrodes disposed between the lower metal line and the plurality of first upper metal lines, and extending in the second direction, wherein the plurality of gate electrodes are spaced apart from each other in the first direction;
a first source/drain region disposed between the plurality of gate electrodes,
a second source/drain region disposed between the plurality of gate electrodes and spaced apart from the first source/drain region in a third direction;
a first active pattern connected to the first source/drain region and disposed in the gate electrode; and
a second active pattern connected to the second source/drain region and disposed in the gate electrode, wherein the second active pattern is spaced apart from the first active pattern in the third direction,
wherein the first direction, the second direction and the third direction intersect each other.

11. The semiconductor device of claim 10, wherein three or four first upper metal lines of the plurality of first upper metal lines are disposed between the first and second power wirings.

12. The semiconductor device of claim 10, further comprising:
a first active contact electrically connected to the first source/drain region and disposed between the lower metal line and the first source/drain region.

13. The semiconductor device of claim 10, wherein a width of each of the first and second power wirings in the second direction is greater than a width of the lower metal line in the second direction.

14. The semiconductor device of claim 10, further comprising:
a second upper metal line extending in the second direction on the first upper metal line and connected to the first upper metal line.

15. The semiconductor device of claim 10, further comprising:
a first gate contact configured to electrically connect some of the plurality of gate electrodes to the lower metal line.

16. The semiconductor device of claim 15, further comprising:
a plurality of second gate contacts configured to electrically connect the plurality of gate electrodes to the first upper metal line and disposed between each of the plurality of gate electrodes and each of the plurality of first upper metal lines.

17. A semiconductor device comprising a standard cell region, wherein the standard cell region comprises:
first and second active patterns spaced apart from each other in a third direction;
a plurality of gate electrodes covering the first and second active patterns, and extending in a second direction, wherein the plurality of gate electrodes are spaced apart from each other in a first direction;
a first source/drain region disposed between the plurality of gate electrodes and connected to the first active pattern;
a second source/drain region disposed between the plurality of gate electrodes and connected to the second active pattern;
a plurality of first upper metal lines extending in the first direction on the second active pattern and spaced apart from each other in the second direction;
a lower metal line extending in the first direction under the first active pattern;
a first power wiring disposed on a same level as the lower metal line, and extending in the first direction, wherein the first power wiring is configured to supply a first power voltage to the first source/drain region;
a second power wiring extending in parallel with the first power wiring and configured to supply a second power voltage different from the first power voltage to the second source/drain region;
a first gate contact configured to electrically connect some of the plurality of gate electrodes to the lower metal line that is under the plurality of gate electrodes;
a plurality of second gate contacts electrically configured to connect the plurality of gate electrodes to the first upper metal line that is disposed on each of the plurality of gate electrodes;
a first active contact electrically connected to the first source/drain region that is disposed under the first source/drain region; and
a first active via disposed between the lower metal line and the first active contact and configured to electrically connect the lower metal line to the first active contact,
wherein when viewed in a plan view, three or four first upper metal lines of the plurality of first upper metal lines are disposed between the first and second power wirings,
a width of each of the first and second power wirings in the second direction is greater than a width of the lower metal line in the second direction, and
the first direction, the second direction and the third direction intersect each other.

18. The semiconductor device of claim 17, further comprising:
a second active contact electrically connected to the second source/drain region and disposed between the first upper metal line and the second source/drain region.

19. The semiconductor device of claim 18, further comprising:
a via contact disposed between the first active contact and the second active contact and configured to electrically connect the first active contact to the second active contact.

20. The semiconductor device of claim 17, further comprising:
a second upper metal line extending in the second direction on the first upper metal line and connected to the first upper metal line.
